(19) United States
(12) Patent Application Publication
(10) Pub. No.: US 2009/0008714 A1
(43) Pub. Date: Jan. 8, 2009

(54) SEMICONDUCTOR DEVICES AND METHODS OF FORMING THE SAME

(76) Inventor: HEE-IL CHAE, Seoul (KR)

Correspondence Address: F. CHAU & ASSOCIATES, LLC, 130 WOODBURY ROAD, WOODBURY, NY, 11797, US

(21) Appl. No.: 12/167,839

(22) Filed: Jul. 3, 2008

(30) Foreign Application Priority Data
Jul. 6, 2007 (KR) 2007-68131

(51) Int. Cl. H01L 29/786; H01L 21/336

(52) U.S. Cl. 257/347; 438/157; 257/E21.411; 257/E29.264

(57) ABSTRACT

A semiconductor device includes a semiconductor layer disposed between a semiconductor substrate and a gate electrode, a back gate insulating layer pattern disposed between the semiconductor layer and the semiconductor substrate, and a gate insulating layer disposed between the semiconductor layer and the gate electrode. The semiconductor substrate extends from both sides of the back gate insulating layer pattern to the gate insulating layer and is directly in contact with a sidewall of the semiconductor layer.

### CROSS-REFERENCE TO RELATED APPLICATIONS

This U.S. non-provisional patent application claims priority to Korean Patent Application No. 2007-68131, filed on Jul. 6, 2007, the entire contents of which are hereby incorporated by reference herein in its entirety.

### BACKGROUND OF THE INVENTION

1. Technical Field

The present disclosure relates to semiconductor devices and methods of forming the same, and more particularly, to a capacitorless DRAM device and a method of forming the same.

2. Description of the Related Art

A conventional DRAM may include 1 transistor and 1 capacitor (1T/1C). However, when the 1T/1C DRAM is highly integrated and embedded in a chip with other devices, the forming a capacitor of 1T/1C DRAM may require a complex process. DRAMs using silicon on insulator (SOI) that can store data without a capacitor have been introduced and one of the DRAMs is the capacitorless DRAM that stores charges in a body of a substrate.

When a uniform voltage is applied to a gate and a drain of the capacitorless DRAM using an SOI substrate, a hot carrier, that is, an excess hole may be generated in a channel body of the substrate. As an oxide barrier is formed under the channel body, the generated hole may be confined to the channel body. A threshold voltage of the gate when the excess hole is confined to the channel body may be different from a threshold voltage of the gate when the excess hole ejects from the channel body. A state when the excess hole is confined to the channel body is defined as a logic “1” and a state when the excess hole ejects from the channel body by forcing a current between a source and a drain is defined as a logic “0”. When a corresponding transistor is selected, a threshold voltage of the gate is different according to a logic “1” or a logic “0” and a level of a current that flows to a source and a drain is different. A reading operation is performed using the difference of the current.

As time is elapsed, an excess hole in the channel body disappears by a recombination. The duration that excess holes exist is referred to as a retention time. Moreover, an SOI substrate may be expensive and as a crystalline defect may occur between an insulating layer and a silicon crystal, its reliability may be degraded.

### SUMMARY OF THE INVENTION

In accordance with an exemplary embodiment of the present invention, a semiconductor device is provided. The semiconductor device includes a semiconductor layer disposed between a semiconductor substrate and a gate electrode,., a back gate insulating layer pattern disposed between the semiconductor layer and the semiconductor substrate, and a gate insulating layer disposed between the semiconductor layer and the gate electrode. The semiconductor substrate extends from both sides of the back gate insulating layer pattern to the gate insulating layer and is directly in contact with a sidewall of the semiconductor layer.

In accordance with an exemplary embodiment of the present invention, a method of forming a semiconductor device is provided. The method includes forming a back gate trench in a predetermined region of a semiconductor substrate, forming a back gate insulating layer pattern that covers at least a bottom surface of the back gate trench, and forming a semiconductor layer that is disposed on the back gate insulating layer pattern and fills the back gate trench. The semiconductor layer has the same crystalline structure as the semiconductor substrate adjacent to back gate insulating layer pattern.

### BRIEF DESCRIPTION OF THE FIGURES

Exemplary embodiments of the present invention can be understood in more detail from the following description taken in conjunction with the accompanying drawings, in which:

FIGS. 1a to 1f are perspective views illustrating a method of forming a semiconductor device in accordance with an exemplary embodiment of the present invention;

FIGS. 2 to 4 are perspective views of a semiconductor device in accordance with an exemplary embodiment of the present invention;

FIGS. 5a and 5b are top plan views illustrating a method of forming a semiconductor device in accordance with an exemplary embodiment of the present invention;

FIGS. 6a to 6f are cross sectional views illustrating a method of forming a semiconductor device in accordance with an exemplary embodiment of the present invention;

FIG. 7 is a perspective view of a semiconductor device in accordance with an exemplary embodiment of the present invention; and

FIGS. 8 to 14 are cross sectional views of a semiconductor device in accordance with an exemplary embodiment of the present invention.

### DETAILED DESCRIPTION OF EXEMPLARY EMBODIMENTS OF THE INVENTION

The present invention now will be described more fully hereinafter with reference to the accompanying drawings, in which exemplary embodiments of the invention are shown. This invention may, however, be embodied in many different forms and should not be construed as limited to the exemplary embodiments set forth herein. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

The terminology used herein is for the purpose of describing particular exemplary embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Exemplary embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

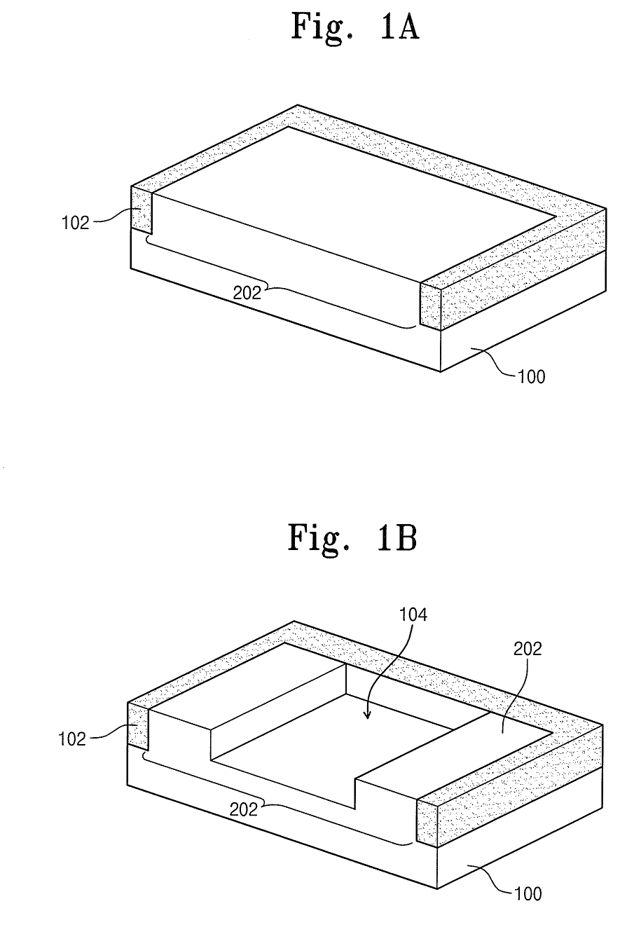

FIGS. 1a to 1f are perspective views illustrating a method of forming a semiconductor device in accordance with an exemplary embodiment of the present invention.

A method of forming the semiconductor device includes a step of forming a back gate trench 104 on a predetermined region of a semiconductor substrate 100, a step of forming a back gate insulating layer pattern 108 covering a bottom surface of the back gate trench 104, and a step of forming a semiconductor layer 110 that is disposed on the back gate insulating layer pattern 108 and fills the back gate trench 104. Here, the semiconductor layer 110 has the same crystalline structure as the semiconductor substrate 100 near the back gate insulating layer pattern 108.

Referring to FIG. 1a, an active region 202 is defined by a device isolation layer 102. The semiconductor substrate 100 may be, for example, a silicon substrate or a germanium substrate. The semiconductor substrate 100 may be, for example, a p-type substrate. The device isolation layer 102 may be, for example, a silicon oxide layer, a silicon nitride layer, silicon oxynitride layer, or a combination thereof. The device isolation layer 102 may be formed using a shallow trench isolation (STI) process.

Referring to FIG. 1b, the back gate trench 104 may be formed in the active region 202 using, for example, a photolithography process and an etching process. For example, the active region 202 is etched using the device isolation layer 102 and a photoresist pattern as a mask to form the back gate trench 104. The back gate trench 104 may have a square-shaped configuration on a top plan view. The back gate trench 104 may have a depth of about 1 nm to about 500 nm. A lower surface of the back gate trench 104 may be higher than a lower surface of the device isolation layer 102. A side surface of the back gate trench 104 may be perpendicular to an upper surface of the semiconductor substrate 100. According to another exemplary embodiment of the present invention, the shape and the angle of the back gate trench 104 may be variously changed.

Referring to FIG. 1c, a back gate insulating layer 106 may be formed on the semiconductor substrate 100 including the back gate trench 104. The back gate insulating layer 106 may conformally cover the lower surface and the side surface of the back gate trench 104. The back gate insulating layer 106 may include, for example, at least one of a silicon oxide layer, a silicon nitride layer, a silicon oxynitride layer, or a combination thereof. The back gate insulating layer 106 may have a depth of about 1 nm to about 200 nm. The back gate insulating layer 106 may be formed using, for example, a chemical vapor deposition (CVD) process or an atomic layer deposition (ALD) process. The silicon oxide layer may be, for example, a thermal oxide layer.

Referring to FIG. Id, a buffer layer 109 may be formed on the semiconductor substrate 100 including the back gate insulating layer 106. The buffer layer 109 may include, for example, at least one of a photoresist layer, an organic layer, a silicon oxide layer, a silicon nitride layer and a polysilicon. The buffer layer 109 may fill the back gate trench 104. The photoresist layer may be formed using, for example, a spin coating method. A material of the back gate insulating layer 106 may be different from a material of the buffer layer 109.

The buffer layer 109 may be planarized down to an upper surface of the active region 202. The planarization may be performed using, for example, a chemical mechanical polishing (CMP) process or an etched back process.

For example, the buffer layer 109 is planarized down to the upper surface of the active region 202 using a chemical mechanical polishing (CMP) process. A buffer layer 109 filling the back gate trench 104 may remain in the back gate trench 104. The back gate insulating layer 106 may be additionally etched using the buffer layer 109 and the active region 202 as a mask. In this case, the back gate insulating layer 106 is recessed to be lower than the upper surface of the active region 202. As a result, a back gate insulating layer pattern 108 is formed. A sidewall of the back gate trench 104 may be exposed by an additional etching of the back gate insulating layer 106. The additional etching may be, for example, an anisotropic etching or an isotropic etching.

According to the etched back process, the buffer layer 109 may be etched back until the active region 202 is exposed. A buffer layer 109 filling the back gate trench 104 may remain in the back gate trench 104. The back gate insulating layer 106 may be additionally etched using the buffer layer 109 and the active region 202 as a mask to form the back gate insulating layer pattern 108. The sidewall of the back gate trench 104 may be exposed by an additional etching of the back gate insulating layer 106.

According to another exemplary embodiment of the present invention, the back gate insulating layer pattern 108 may be changed to various shapes so long as an upper surface of the back gate insulating layer pattern 108 is lower than an upper surface of the active region 202.

Referring to FIG. 1e, a portion of the buffer layer 109 on the back gate insulating layer pattern 108 may be removed using, for example, an etching process or the buffer layer 109 on the back gate insulating layer pattern 108 may be entirely removed using an etching process.

If the buffer layer 109 is entirely removed, a semiconductor layer 110 covering the upper surface of the back gate insulating layer pattern 108 is formed. If the buffer layer 109 remains on the gate insulating layer pattern 108, the semiconductor layer 110 covers an upper surface of the buffer layer 109. The semiconductor layer 110 may be, for example, crystalline silicon. The semiconductor layer 110 may be formed using, for example, a deposition/annealing technique or a crystal growth technique. The semiconductor layer 110 and the semiconductor substrate 100 are formed of a semiconductor material having a single crystalline structure, respectively. In this case, the semiconductor layer 110 may have the same structure as the semiconductor substrate 100.

The deposition/annealing technique may include, for example, a step of depositing a semiconductor material layer that is directly in contact with the semiconductor substrate 100 on the back gate insulating layer pattern 108 and a step of annealing the semiconductor material layer so that the semiconductor material layer has a single crystalline structure transferred from the semiconductor substrate 100. The semiconductor material layer may, for example, have an amorphous structure or a polycrystal structure.

The semiconductor material layer may be a doped semiconductor material layer. After the semiconductor material layer is deposited, the semiconductor substrate 100 may be planarized down to an upper portion of the device isolation layer 102. If the annealing process is then performed, the deposited semiconductor material layer is crystallized and becomes the semiconductor layer 110. The annealing process may be performed at a temperature of above 700° C. The order of the planarization process and the annealing process may be changed.

The crystal growth technique may form the semiconductor layer using a selective epitaxial growth (SEG) technique. The crystallized semiconductor layer 110 may be formed using crystal silicon of the active region 202 as a seed to fill the back gate trench 104. The semiconductor layer 110 is planarized down to an upper surface of the device isolation layer to form the semiconductor layer 110. The doping and growth of the semiconductor layer 110 may be performed at same time.

A method of forming the semiconductor layer 110 is not limited to the methods described above. For example, an atomic layer deposition (ALD) process, and a combination of the ALD process and the selective epitaxial growth (SEG technique may be applied to forming the semiconductor layer 110.

Referring to FIG. 1f, a gate insulating layer 114 is formed on the substrate 100 including the semiconductor layer 110. The gate insulating layer 114 may be formed on the active region 202 and the semiconductor layer 110. The gate insulating layer 114 may include, for example, at least one of a silicon oxide layer and a silicon oxynitride layer. The silicon oxide layer may be, for example, a thermal oxide layer.

A gate conductive layer may be formed on the gate insulating layer 114. The gate conductive layer may include, for example, at least one of (among) doped polysilicon, metal and metal nitride. The gate conductive layer may be patterned to form a gate electrode 116. The gate insulating layer 114 on the active region 202 adjacent to the gate electrode 116 may be removed. The gate electrode 116 may include a hard mask pattern.

Impurities are implanted into the active region 202 using the gate electrode 116 as a mask to form impurity regions 120. The impurity region 120 formed in the active region 202 may be formed to be deeper than an upper surface of the back gate insulating layer pattern 108. The impurity region 120 may be in contact with the back gate insulating layer pattern 108. According to another exemplary embodiment, the ion implantation process may be performed after the formation of a spacer 118 which will be described later

If the semiconductor layer 110 is a P-type, the impurity region 120 may be an N-type. If the semiconductor layer 110 is an N-type, the impurity region 120 may be a P-type. Accordingly, the impurity region 120 and the semiconductor substrate 100 may form a PN junction. The impurity region 120 and the semiconductor layer 110 may form a PN junction.

If comparing with a MOSFET using an ordinary bulk substrate, the device of the present invention includes the back gate insulating layer pattern 108. The back gate insulating layer pattern 108 electrically separates the semiconductor substrate 100 and the semiconductor layer 110 to cut off a path where currents can flow. The semiconductor layer 110 may be connected to the semiconductor substrate 100 through the impurity region 120. If a reverse bias is applied between the impurity region 120 and the semiconductor substrate 100, the semiconductor layer 110 and the semiconductor substrate 100 are electrically separated because the impurity region 120 and the semiconductor substrate 100 form a PN junction. Thus, the back gate insulating layer pattern 108 may function as an insulating layer of the SOI substrate. In the device of exemplary embodiments of the present invention, a capacitorless DRAM embodied using a SOI substrate may be embodied using a bulk silicon substrate.

In the meantime, according to another exemplary embodiment of the present invention, spacers 118 may be further disposed on both sides of the gate electrode 116. After a spacer layer is formed on the gate electrode 116, the spacer layer may be anisotropically etched to form the spacers 118. According to another exemplary embodiment of the present invention, a silicide layer may be further formed on the gate electrode 116 and the impurity region 120. In the case that the gate electrode 116 is formed of polysilicon, the silicide layer may be formed using a self aligned silicidation process.

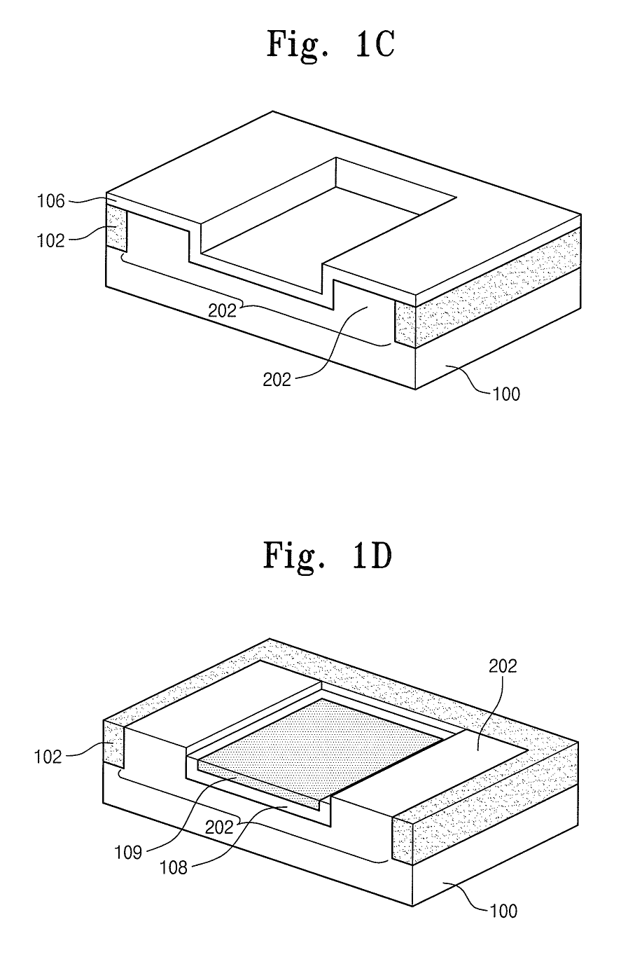

FIG. 2 is a perspective view of a semiconductor device in accordance with an exemplary embodiment of the present invention.

Referring to FIG. 2, the device includes at least one gate electrode 116 on a semiconductor substrate 100, a semiconductor layer 110 between the semiconductor substrate 100 and the gate electrode 116, a back gate insulating layer pattern 108 between the semiconductor layer 110 and the semiconductor substrate 100, and a gate insulating layer 114 between the semiconductor layer 110 and the gate electrode 116. The semiconductor substrate 100 extends from both sides of the back gate insulating layer pattern 108 toward the gate insulating layer 114 and is directly in contact with sidewalls of the semiconductor layer 110. The device may have a conductivity type different from the semiconductor substrate 100 and may further include impurity regions 120 formed in an extended portion of the semiconductor substrate 100.

The semiconductor substrate 100 may be, for example, a silicon substrate or a germanium substrate. The semiconductor substrate 100 and the semiconductor layer 110 may be in contact with each other on both sides of the back gate insulating layer pattern 108. The device may further include device isolation layers 102.

The device isolation layers 102 define an active region 202. The device isolation layers 202 are disposed to reduce interference between the adjacent devices. The device isolation layer 202 may include, for example, at least one of a silicon oxide layer, a silicon nitride layer and a combination thereof.

The back gate insulating layer pattern 108 is disposed between the semiconductor substrate 100 and the semiconductor layer 110. The back gate insulating layer pattern 108 may include, for example, at least one of a silicon oxide layer and a silicon nitride layer.

The gate insulating layer 114 and the gate electrode 116 are disposed on the semiconductor layer 110. Impurity regions may be disposed in the active region 202 adjacent to the gate electrode 116 and/or in the semiconductor layer 110. An upper surface of the back gate insulating layer pattern 108 may be higher than a lower surface of the impurity region 120. The back gate insulating layer pattern 108 and the impurity region 120 may be in contact with each other. Thus, the semiconductor layer 110 may be electrically separated from the semiconductor substrate 100 by the impurity region 120 and the back gate insulating layer pattern 108.

The semiconductor layer 110 may be the same crystalline structure as the semiconductor substrate 100. The semiconductor layer 110 and the semiconductor substrate 100 are formed of a single crystalline structure semiconductor material, respectively and the single crystalline structure of the semiconductor substrate 100 may be continuously connected to the semiconductor layer 110.

The semiconductor layer 110 may have a conductivity type opposite to the impurity region 120. The impurity region 120 may function as source/drain of a MOSFET.

The device of the present invention may have a structure of the back gate insulating layer pattern 108 and a P-type semiconductor layer 110 on a P-type semiconductor substrate 100 to form a NMOS device. The back gate insulating layer pattern 108 may be disposed between the semiconductor layer 110 and the semiconductor substrate 100 to cut off currents between the semiconductor layer 110 and the semiconductor substrate 100. If a reverse bias is applied to a PN junction between the impurity region 120 and the semiconductor substrate 100, the semiconductor layer 110 and the semiconductor substrate 100 may be electrically separated.

In case of a NMOS device, the semiconductor layer 110 is a P-type and the impurity region 120 is an N-type. An upper surface of the back gate insulating layer pattern 108 is higher than a lower surface of the impurity region 120. The impurity region 120 may be in contact with the back gate insulating layer pattern 108. Accordingly, the semiconductor layer 110 and the semiconductor substrate 100 are electrically separated. Excess holes stored in the a P-type semiconductor layer 110 (or a channel body) are surrounded with a potential well by the back gate insulating layer pattern 108 and the impurity region 120 and cannot go out of the potential well. A reverse bias is applied between the P-type semiconductor layer 110 and the N-type impurity region 120 to reduce currents due to the PN junction. Charges stored in the semiconductor layer 110 change a threshold voltage of the gate electrode 116. Thus, the above NMOS device may be used as a memory device.

The back gate insulating layer pattern 108 is constituted so that the P-type semiconductor layer 110 is not directly in contact with the P-type substrate 100. The back gate insulating layer pattern 108 may change to various shapes. A buffer layer 109 may be disposed between the back gate insulating layer pattern 108 and the semiconductor layer.

A gate insulating layer 114 may be disposed on the semiconductor layer 110 and the active region 202. The gate insulating layer 114 may include, for example, at least one of a silicon oxide layer or a silicon oxynitride layer.

The gate electrode 116 is disposed on the gate insulating layer 114. A spacer 118 may be disposed on a side surface of the gate electrode 116. The gate electrode 116 may be conductive material. The spacer 118 may be, for example, at least one of a silicon oxide layer, a silicon nitride layer and a combination thereof.

The impurity regions 120 may become a source and a drain, and electrically connected to an external electric circuit.

According to another exemplary embodiment, a lower surface of the impurity region 120 may be higher than an upper surface of the back gate insulating layer pattern 108. The impurity regions 120 may not be in contact with the back gate insulating layer pattern 108. The semiconductor layer 110 may be directly in contact with the semiconductor substrate 100. In this case, the device of the present invention may be used as an ordinary MOSFET rather than a memory device.

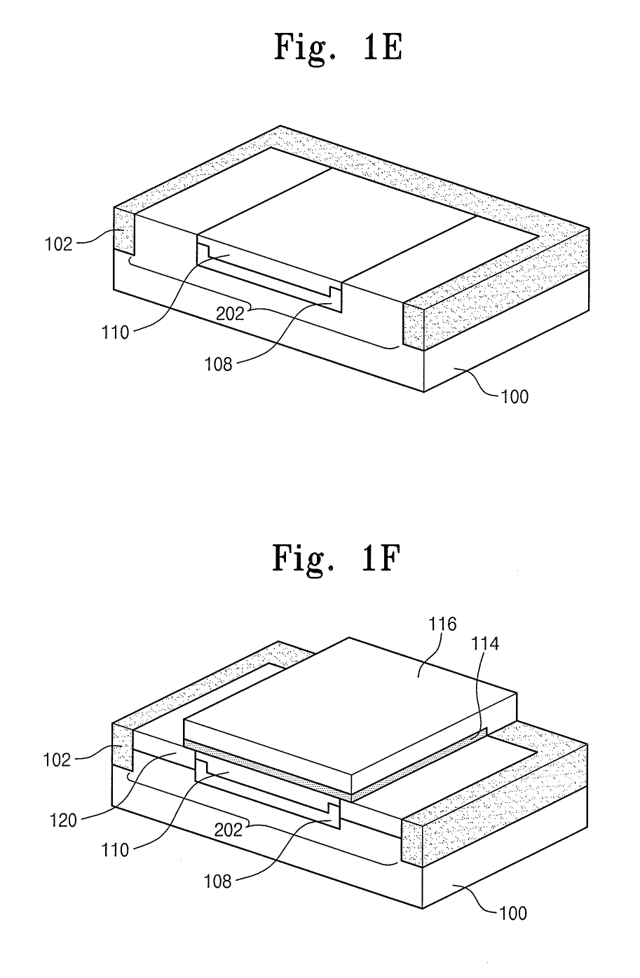

FIG. 3 is perspective view of a semiconductor device in accordance with an exemplary embodiment of the present invention.

Referring to FIG. 3, a buffer layer 109 may be disposed on the back gate insulating layer pattern 108. The buffer layer 109 and the back gate insulating layer pattern 108 cut off a direct contact of the semiconductor layer 110 and the semiconductor substrate 100 under the back gate insulating layer pattern 108. The buffer layer 109 and the back gate insulating layer pattern 108 may be changed to various shapes. The buffer layer 109 may include at least, for example, one of a silicon nitride layer, a silicon oxide layer and an organic layer.

Impurity regions 120 adjacent to the back gate insulating layer pattern 108 and the semiconductor substrate 100 constitute a PN junction. A reverse bias is applied to the PN junction. A lower surface of the impurity regions 120 is higher than an upper surface of the back gate insulating layer pattern 108. The impurity region 120 may be directly in contact with the back gate insulating layer pattern 108.

The width (a) of the gate electrode 116 may be greater than the width (b) of the back gate insulating layer pattern 108. In the case that the width (a) of the gate electrode 116 may be greater than the width (b) of the back gate insulating layer pattern 108, an ion implantation process or a diffuse process may be performed so that the impurity region 120 is in contact with the back gate insulating layer pattern 108.

When a voltage is applied to the gate electrode 116, a thickness (c) of the semiconductor layer 110 may be about 1 nm to about 100 nm so that the semiconductor layer 110 is fully depleted. The depth (d) of the impurity region 120 may be greater than the thickness (c) of the semiconductor layer 110. The depth (d) of the impurity region 120 may change according to a type of the back gate insulating layer pattern 108. The semiconductor layer 110 may be doped. The conductivity type and the concentration of the semiconductor layer 110 may change according to a kind of the device and a threshold voltage of the device.

The semiconductor substrate 100 may include wells 126 and 112. The wells may be divided into a deep well 126 and a well 112. The deep well 126 is formed to isolate devices and a well 112 is formed to form devices.

The deep well 126 may be formed to isolate a plurality of devices from other devices. The deep well 126 may be formed in the semiconductor substrate 100 to isolate devices after the device isolation layer 102 is formed. The deep well 126 may be formed using an ion implantation process. When a semiconductor memory device is formed, the deep well 126 may be used to isolate cell devices from peripheral devices. The deep well 126 may be formed in the semiconductor substrate 100 to be lower than a lower surface of the device isolation layer 102. In the case of NMOS device, the deep well may be an N-type.

A well 112 for forming a device may be formed in the semiconductor substrate 100. The well 112 may be formed using, for example, an ion implantation process. The well 112 may be formed to be deeper than a lower surface of the device isolation layer 102. In the case of a NMOS device, the well 112 may be a P-well. A conductivity type of the well 112 may alter according to a NMOS device or a PMOS device.

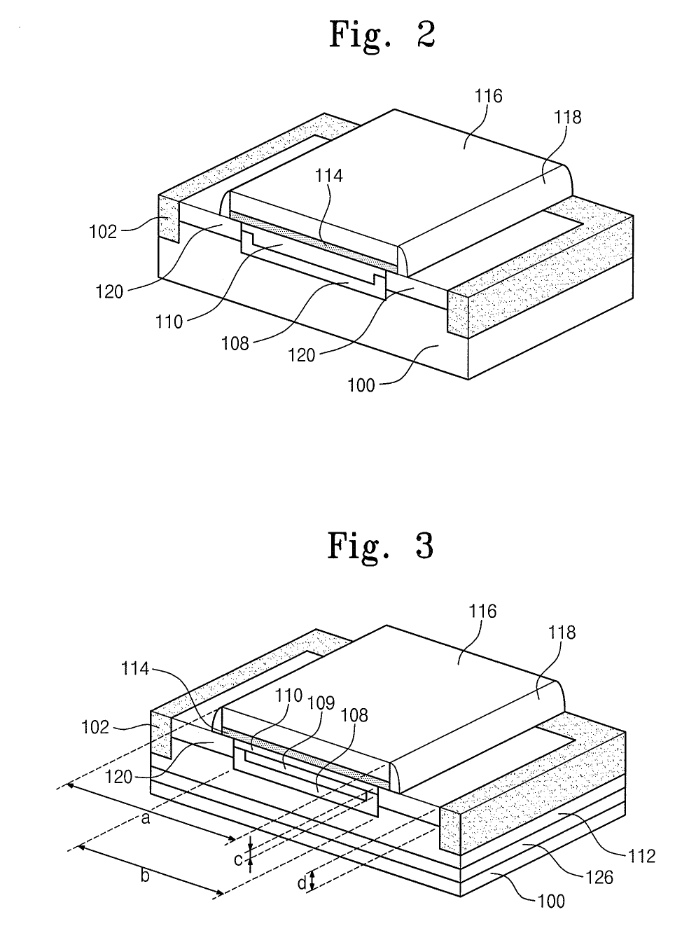

FIG. 4 is perspective view of a semiconductor device in accordance with an exemplary embodiment of the present invention.

Referring to FIG. 4, the width (b) of the back gate insulating layer pattern 108 may be greater than the width (a) of the gate electrode 116. The width of the semiconductor layer 110 formed on the back gate insulating layer pattern 108 may be greater than the width of the gate electrode 116.

As described in FIG. 1e, the semiconductor layer 110 may be formed using a selective epitaxial growth technique. Alternatively, the semiconductor layer 110 may also be formed by, for example, depositing a semiconductor layer, annealing the semiconductor layer and crystallizing the semiconductor layer.

An impurity region 120 may be formed in a portion of the semiconductor layer 110 and the active region 202. For example, an ion implantation process is performed using the gate electrode 116 as a mask to form a first impurity region 120a in the semiconductor layer 110 adjacent to the gate electrode 116 and a second impurity region 120b in the active region 202. The first impurity region 120a may have the same depth as the second impurity region 120b. The second impurity region 120b may be formed to be deeper than an upper surface of the back gate insulating layer pattern 108. The impurity region 120 may be in contact with the back gate insulating layer pattern 108.

In the case of NMOS device, the semiconductor layer 110 is a P-type, the first and second impurity regions 120a and 120b are an N-type, and the semiconductor substrate 100 is a P-type. In this case, if a reverse bias is applied to the impurity region 120 and the semiconductor substrate 100, the semiconductor layer 110 and the semiconductor substrate 100 are electrically cut off by the impurity region 120 which constitutes a PN junction.

A conductivity type of the semiconductor layer 110 and the impurity region 120 may alter according to an NMOS device or a PMOS device. In the case of the PMOS device, conductivity types of the semiconductor layer 110 and the impurity region 120 may alter according to a surface channel type or a buried channel type.

The impurity region 120 becomes a source and a drain. The source and the drain may be electrically connected to an external circuit.

The semiconductor device of exemplary embodiments of the present invention is not limited to a semiconductor memory device.

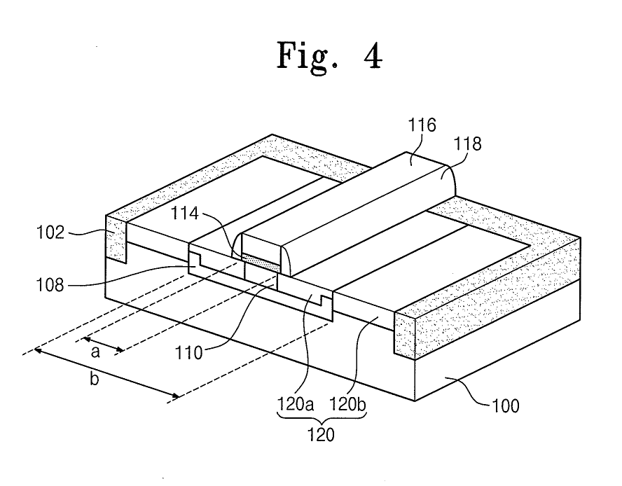

FIGS. 5a and 5b are top plan views illustrating a method of forming a semiconductor device in accordance with an exemplary embodiment of the present invention. This exemplary embodiment shows embodiments applied to a capacitorless DRAM device.

Referring to FIG. 5a, active regions 202 and a device isolation layer 102 are formed in a semiconductor substrate 100. This device may include active regions 202 used in 8F2 technique. The active regions 202 may be disposed in row and column with a uniform space. The active regions 202 may change to various shapes. A step of doping the active regions 202 may be further included after the device isolation layer 102 is formed.

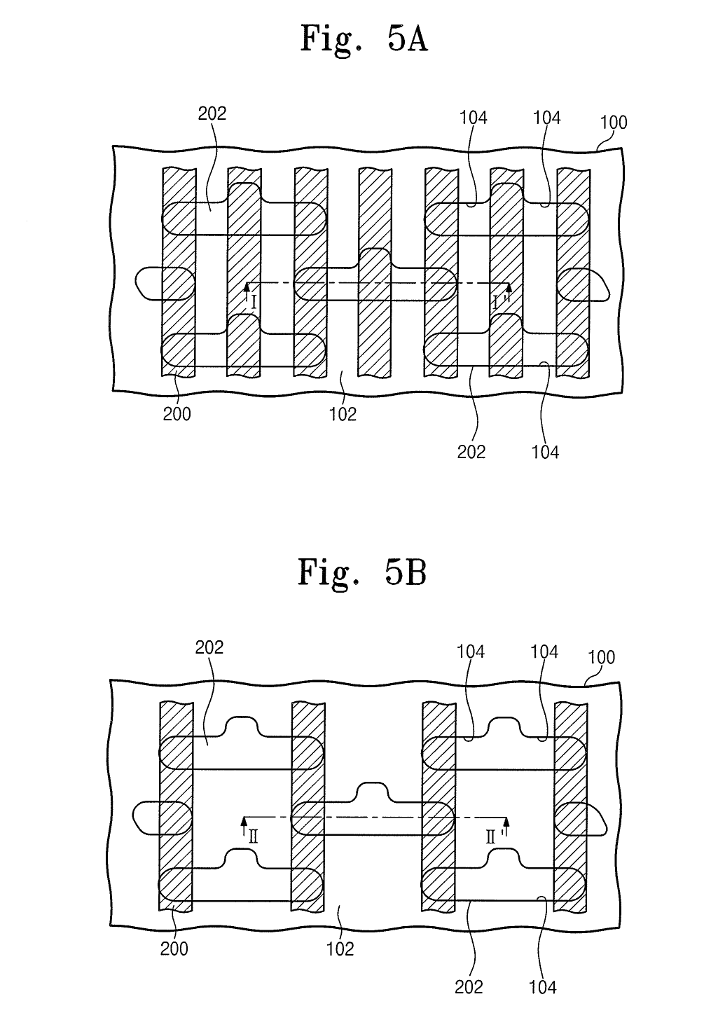

Photoresist patterns 200 are formed on the semiconductor substrate 100 including the active regions 202. The three photoresist patterns 200 cross the one active region 202. For example, the two photoresist patterns 200 cross both edges of the active regions 202 and the one photoresist pattern 200 crosses a center of the active regions 202. The active regions 202 are etched using the photoresist patterns 200 and the device isolation layer 102 as an etching mask. As shown in FIG. 6a, a pair of back gate trenches 104 are formed in the one active region 202.

Referring to FIG. 5b, active regions 202 and a device isolation layer 102 are formed in a semiconductor substrate 100. Photoresist patterns 200 are formed on the semiconductor substrate 100. The two photoresist patterns 200 with a uniform space cross the active regions 202. For example, the two photoresist patterns 200 cross both edges of the active regions 202. The active regions 202 are etched using the photoresist patterns 200 and the device isolation layer 102 as an etching mask.

According to another exemplary embodiment of the present invention, this device may include active regions 202 used in 6F2 technique. Photoresist patterns 200 are formed on the semiconductor substrate 100 including the device isolation layer 102. A major axis of the photoresist pattern 200 may make a predetermined angle with a major axis of the active region 202. The active regions 202 are etched using the photoresist patterns 200 and the device isolation layer 102 as an etching mask.

The type of the active regions 202 of the present invention is not limited to these embodiments and may be variously changed.

FIGS. 6a to 6f are cross sectional views illustrating a method of forming a semiconductor device in accordance with an exemplary embodiment of the present invention. FIGS. 6a to 6f are cross sectional views taken along the line I-I′ of FIG. 5a.

Referring to FIG. 6a, the photoresist patterns 200 that were described with reference to FIG. 5a are formed. Active regions 202 are etched using the photoresist patterns 200 and a device isolation layer 102 as an etching mask to form back gate trenches 104. The back gate trenches 104 may be formed to be shallower than the device isolation layer 102.

Referring to FIG. 6b, a back gate insulating layer 106 is formed on the semiconductor substrate 100 including the back gate trenches 104. A buffer layer 109 is formed on the semiconductor substrate 100. The buffer layer 109 may be planarized down to an upper surface of the back gate insulating layer 106. The planarization may be performed using, for example, an etch back process or a chemical mechanical polishing process. The buffer layer 109 may be disposed only on the back gate trenches 104.

Referring to FIG. 6c, the back gate insulating layer 106 may be planarized. The planarization may be performed using, for example, an etch back process or a chemical mechanical polishing (CMP) process. The etch back process may be an etching process that the back gate insulating layer 106 may have an etching selectivity with respect to the buffer layer 109. The chemical mechanical polishing process may be performed until the active regions 202 or the device isolation layer 102 are exposed. The planarized back gate insulating layer 106 may be recessed to form a back gate insulating layer pattern 108.

Referring to FIG. 6d, the buffer layer 109 may be removed. According to another exemplary embodiment of the present invention, only a portion of the buffer layer 109 may be removed. The back gate insulating layer pattern 108 and the remaining buffer layer 109 may be changed to various shapes.

Referring to FIG. 6e, the semiconductor layer 110 may be formed on the semiconductor substrate 100 including the back gate insulating layer pattern 108. A method of forming the semiconductor layer 110 is as follows. First, silicon is deposited on the semiconductor substrate 100. The deposited silicon is then annealed to crystallize the semiconductor layer 110. The semiconductor layer 110 is also formed using a selective epitaxial growth (SEG) technique. The semiconductor layer 110 may be planarized down to an upper surface of the device isolation layer 102.

Referring to FIG. 6f, a gate insulating layer 114 may be formed on the semiconductor layer 110 and the active regions 202. The gate insulating layer 114 may include, for example, at least one of a silicon oxide layer and a silicon oxynitride layer. A gate conductive layer may be formed on the gate insulating layer 114. The gate conductive layer is patterned to form gate electrodes 116. A pair of the gate electrodes 116 may be disposed to be crossing the active regions 202. The gate conductive layer may be a conductive material. The width of the gate electrode 116 may be greater or smaller than the width of the back gate insulating layer pattern 108.

Ion implantation process is performed using the gate electrode 116 as a mask to form an impurity region 120 in the active regions 202 and/or the semiconductor layer 110. The impurity region 120 may be formed to be deeper than an upper surface of the back gate insulating layer pattern 108. The impurity region 120 may be in contact with the back gate insulating layer pattern 108.

A spacer layer is formed on the gate electrodes 116. The spacer layer is anisotropically etched to form spacers 118. The spacers 118 may include, for example, at least one of a silicon oxide layer, a silicon nitride and a combination thereof.

An impurity region 120 between a pair of the gate electrodes 116 becomes drain regions and the drain regions may be electrically connected to an external circuit through bit lines and bit line plugs.

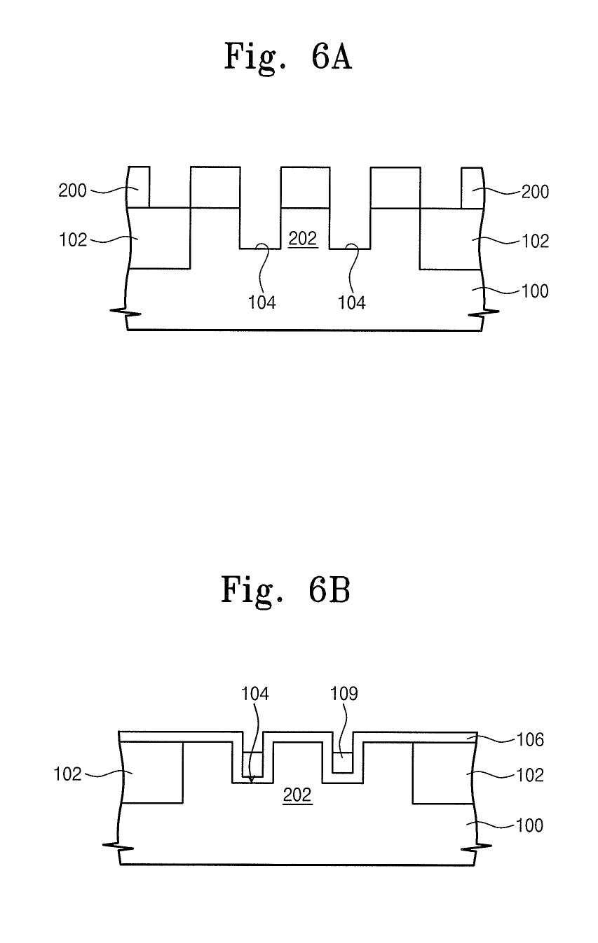

FIG. 7 is a perspective view of a semiconductor device in accordance with an exemplary embodiment of the present invention. FIG. 7 is a perspective view of a cross section taken along the line I-I′ after the semiconductor memory device including the active regions of FIG. 5a is formed.

Referring to FIG. 7, this device includes at least one gate electrode 116 disposed on a semiconductor substrate 100, a semiconductor layer 110 disposed between the semiconductor substrate 100 and the gate electrode 116, and a gate insulating layer 114 disposed between the semiconductor layer 110 and the gate electrode 116. The semiconductor substrate 100 may extend from both sides of a back gate insulating layer pattern 108 toward the gate insulating layer 114 and is directly connected to sidewalls of the semiconductor layer 110. This device may further include impurity regions 120 that have a conductivity type opposite to the semiconductor substrate 100 and are formed in an extended portion of the semiconductor substrate 100. This device includes a pair of the gate electrodes 116 on the semiconductor layer 110 and the back gate insulating layer pattern 108.

For example, the two gate electrodes 116 are disposed on the one active region 202. A gate insulating layer 114, a semiconductor layer 110, and a back gate insulating layer pattern 108 are disposed under the respective gate electrodes 116. The impurity regions 120 are disposed in the active region adjacent to the respective gate electrode 116. The impurity region 120 between a pair of gate electrodes 116 is a drain region and the impurity regions excepting the drain region are source regions. The two transistors may share the drain region. The drain region may be electrically connected to a bit line 152 through a bit line plug 154.

The source regions may be electrically connected to an external circuit through source contact plugs 156.

An upper surface of the back gate insulating layer pattern 108 is higher than a lower surface of the impurity region 120. The impurity region 120 is in 20 contact with the back gate insulating layer pattern 108. The back gate insulating layer pattern 108 may have a groove. The back gate insulating layer pattern 108 may include, for example, at least one of a silicon oxide layer, a silicon nitride layer and a silicon oxynitride layer.

The back gate insulating layer pattern 108 may be smaller than the gate electrode 116.

According to another exemplary embodiment, the back gate insulating layer pattern 108 may be greater than the gate electrode 116. In this case, the impurity regions 120 may be formed in the semiconductor layer 110 and/or the semiconductor substrate 100.

The semiconductor layer 110 may be disposed to be surrounded by the gate insulating layer 114, the impurity regions 120 and the back gate insulating layer pattern 108. The back gate insulating layer pattern 108 may be changed to various shapes. As described in FIG. 2, the impurity regions 120 may have a conductivity type opposite to the semiconductor layer 110 and the semiconductor substrate 100. The semiconductor substrate 100 and the impurity regions 120 may be connected to each other with a PN junction. According to another exemplary embodiment, the semiconductor substrate 100 may have wells.

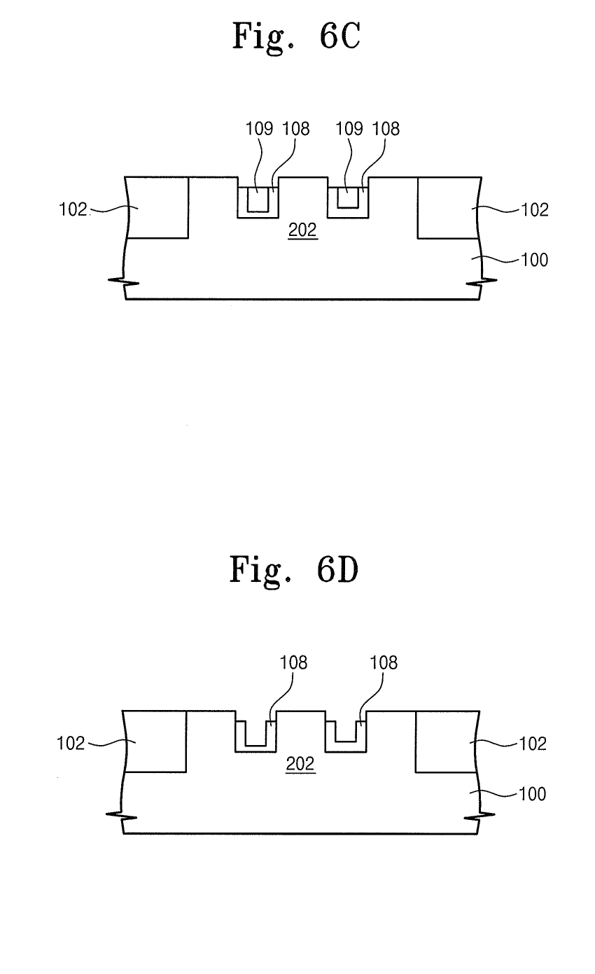

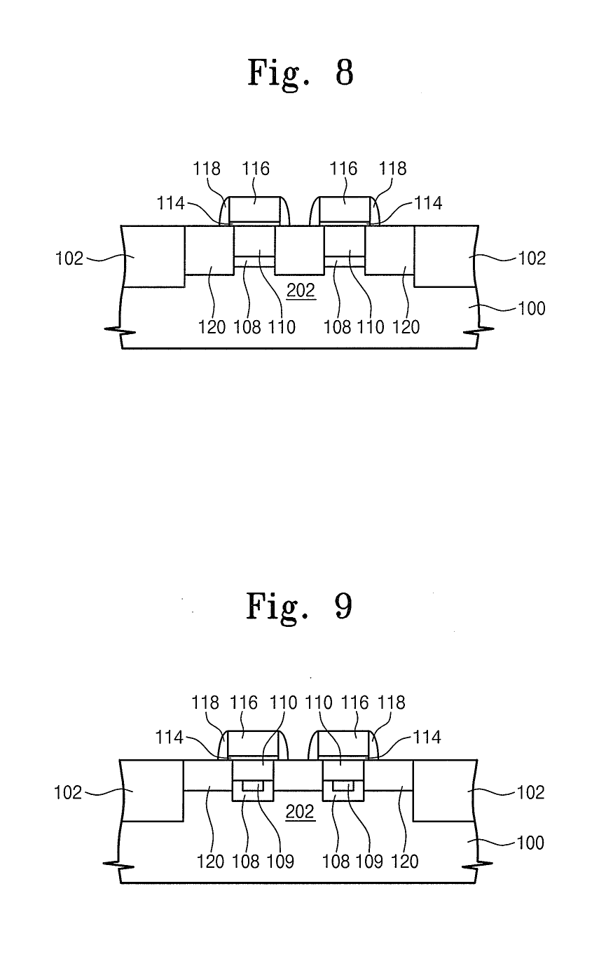

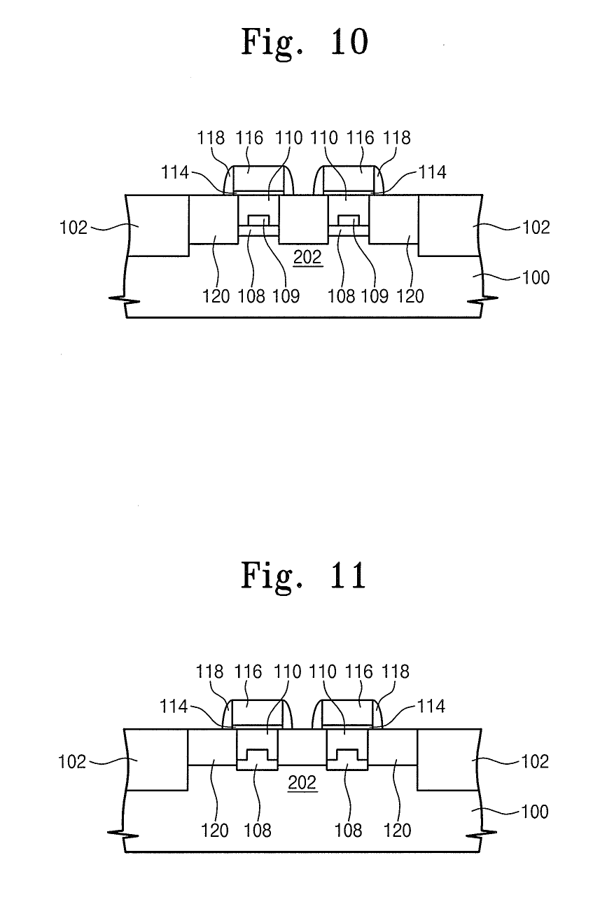

FIGS. 8 to 14 are cross sectional views of a semiconductor device in accordance with another exemplary embodiment of the present invention. FIGS. 8 to 11 are cross sectional views taken along the dotted line I-I′ of FIG. 5a and FIGS. 12 to 14 are cross sectional views taken along the dotted line II-II′ of FIG. 5b. That is, a method of forming the back gate trench with reference to FIG. 5a may be applied to the embodiments illustrated in FIGS. 8 to 11 and a method of forming the back gate trench with reference to FIG. 5b may be applied to the exemplary embodiments illustrated in FIGS. 12 to 14. For brief description, technical features different from the embodiments described previously will be described and the overlapped technical features will be omitted.

Referring to FIGS. 8 to 11, a semiconductor substrate 100 includes at least one active region 202 defined by device isolation layers 102. A pair of gate electrodes 116 crossing the active region 202 are disposed on the active region 202. A back gate insulating layer pattern 108, a semiconductor layer 110 and a gate insulating layer 114 that are sequentially stacked are disposed under the respective gate electrodes 116. The semiconductor layer 110 is disposed between the gate electrode 116 and the semiconductor substrate 100. The back gate insulating layer pattern 108 is disposed the semiconductor layer 110 and the semiconductor substrate 100. The gate insulating layer 114 is disposed between the semiconductor layer 110 and the gate electrode 116. The back gate insulating layer pattern 108 and the semiconductor layer 110 may have a width greater or smaller than the gate electrode 116. As shown in FIG. 8, two of the back gate insulating layer patterns 108 and two of the semiconductor layers 110 are formed in one active region 202.

In the meantime, the semiconductor substrate 100 extends from both sides of the back gate insulating layer pattern 108 toward the gate electrode 116 and is in contact with a sidewall of the semiconductor layer 110. An upper surface of an extended portion of the semiconductor substrate 100 may have the same height as an upper surface of the semiconductor layer 110. Consequently, the extended portion of the semiconductor substrate 100 defines a back gate trench 104 under the gate electrode 116 and the semiconductor layer 110 fills the back gate trench 104.

Impurity regions 120 used as source/drain electrodes of MOS transistor are formed in the extended portion of the semiconductor substrate 100. The impurity regions 120 are formed to have a lower surface lower than an upper surface of the back gate insulating layer pattern 108 and in contact with the back gate insulating layer pattern 108. The impurity regions 120 are doped with conductivity type different from the semiconductor layer 110 and the semiconductor substrate 100. The semiconductor substrate 100 is connected to the impurity regions 120 with a PN junction. The semiconductor layer 110 may be electrically separated from the semiconductor substrate 100.

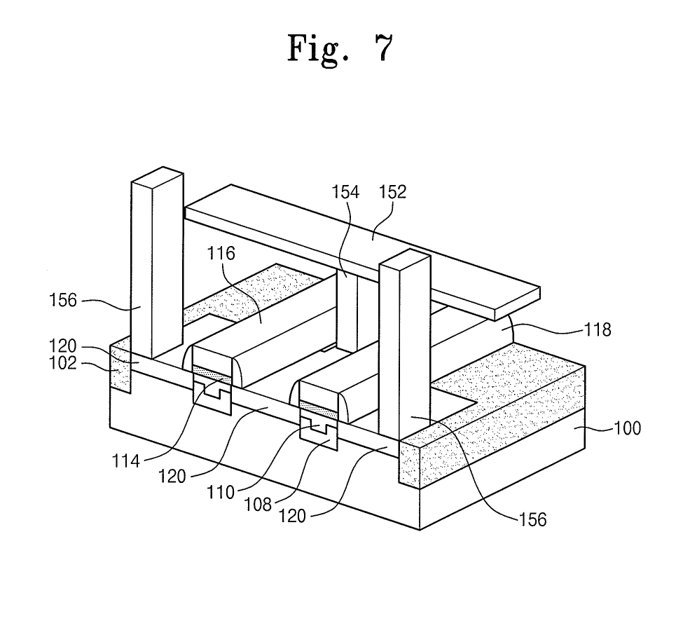

As shown in FIGS. 8 and 10, the back gate insulating layer pattern 108 may have substantially a uniform thickness. A contact area between the semiconductor layer 110 and the impurity regions 120 is substantially the same as the sidewall area of the semiconductor layer 110. According to the exemplary embodiments, to prevent direct contact between the semiconductor layer 110 and the semiconductor substrate 100, the impurity regions 120 are formed to have a lower surface lower than a lower surface of the back gate insulating layer pattern 108.

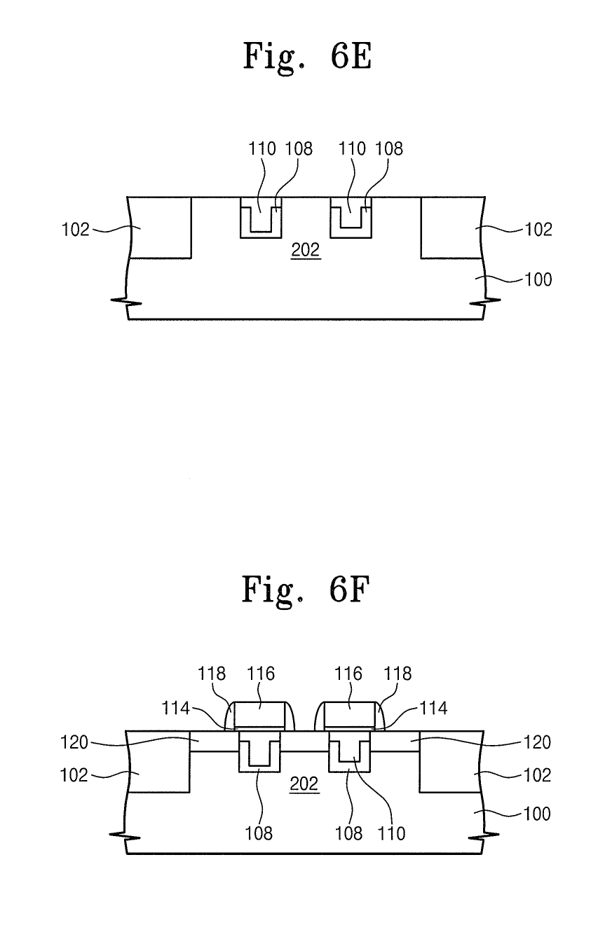

Alternatively, as shown in FIG. 9, an edge (e.g., an inner wall of the back gate trench 104) thickness of the back gate insulating layer pattern 108 may be greater than a center thickness of the back gate insulating layer pattern 108. The back gate insulating layer pattern 108 of this case is substantially the same as the back gate insulating layer pattern of FIG. 7. The impurity regions 120 of this case may have a depth lower than the impurity regions of FIGS. 8 and 10.

Also, as shown in FIG. II, an edge (e.g., an inner wall of the back gate trench 104) thickness of the back gate insulating layer pattern 108 may be smaller than a center thickness of the back gate insulating layer pattern 108. The impurity regions 120 of this case may have a depth higher than the impurity regions of FIGS. 8 and 10.

As shown in FIGS. 9 and 10, a buffer layer 109 is further disposed on the center of the back gate insulating layer pattern 108. The buffer layer 109 may be formed of the same material as the buffer layer of FIG. 3. The back gate insulating layer pattern 108 may be formed to surround the buffer layer 109 as shown in FIG. 9. Alternatively, as the back gate insulating layer pattern 108 of FIG. 10 is formed to have a uniform thickness, a sidewall of the buffer layer 109 is surrounded by semiconductor layer 110.

Referring to FIGS. 12 to 14, one back gate insulating layer pattern 108 and a pair of gate electrodes 116 are disposed in one active region 202. Consequently, a pair of gate electrodes 116 are disposed on one back gate insulating layer pattern 108. As shown in FIGS. 12 to 14, the back gate insulating layer pattern 108 has a width greater than the gate electrode 116.

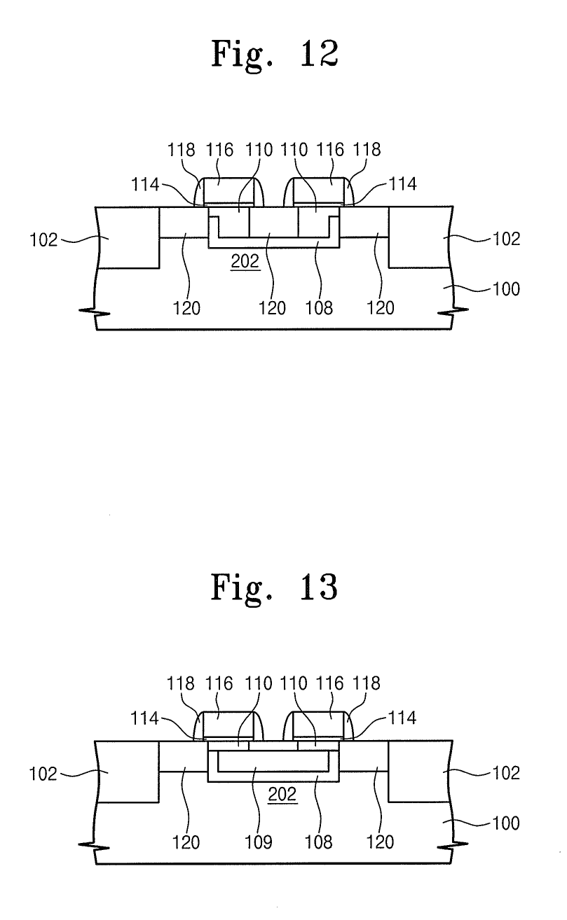

For example, as shown in FIGS. 12 and 13, an edge (e.g., an inner wall of the back gate trench 104) thickness of the back gate insulating layer pattern 108 may be greater than a center thickness of the back gate insulating layer pattern 108. As shown in FIG. 13, a buffer layer 109 may be disposed between the back gate insulating layer pattern 108 and the semiconductor layer 110. In this case, the impurity region 120 in the semiconductor layer 110 between the gate electrodes 116 has a depth smaller than the impurity region 120 in the semiconductor substrate 100.

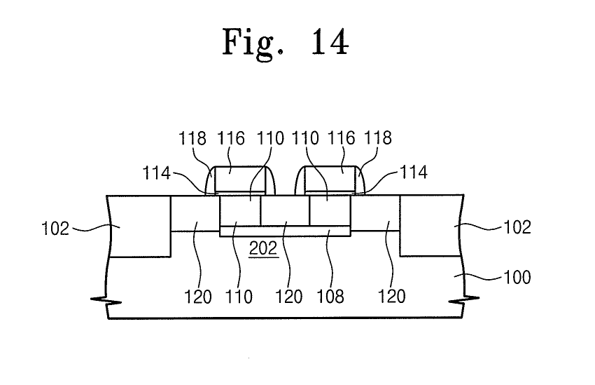

As shown in FIG. 14, the back gate insulating layer pattern 108 may have substantially a uniform thickness. Thus, a contact area between the semiconductor layer 110 and the impurity regions 120 is substantially the same as the sidewall area of the semiconductor layer 110.

According to another exemplary embodiment, the types of the back gate insulating layer pattern 108 and the buffer layer 109 are not limited to these embodiments and may be variously changed.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A semiconductor device, comprising:
a semiconductor layer disposed between a semiconductor substrate and a gate electrode;
a back gate insulating layer pattern disposed between the semiconductor layer and the semiconductor substrate; and
a gate insulating layer disposed between the semiconductor layer and the gate electrode,
wherein the semiconductor substrate extends from both sides of the back gate insulating layer pattern to the gate insulating layer and is directly in contact with sidewalls of the semiconductor layer.

2. The device of claim 1, further comprising impurity regions that have a conductivity type different from the semiconductor substrate and, wherein the impurity regions are formed in an extended portion of the semiconductor substrate.

3. The device of claim 2, wherein the semiconductor layer is electrically separated from the semiconductor substrate by the impurity regions and the back gate insulating layer pattern.

4. The device of claim 2, wherein a lower surface of the impurity regions is lower than an upper surface of the back gate insulating layer pattern.

5. The device of claim 2, wherein the impurity regions are in contact with the back gate insulating layer pattern.

6. The device of claim 1, wherein the impurity regions extend from the semiconductor substrate toward the semiconductor layer under an edge of the gate electrode.

7. The device of claim 1, wherein the semiconductor layer and the semiconductor substrate are formed of a semiconductor material including a single crystalline structure and the single crystalline structure of the semiconductor substrate is transferred to the semiconductor layer.

8. The device of claim 1, wherein a pair of gate electrodes are disposed on the semiconductor layer and the back gate insulating layer pattern.

9. The device of claim 8, further comprising impurity regions that have a conductivity type opposite to the semiconductor substrate and wherein the impurity regions are formed in an extended portion of the semiconductor substrate.

10. The device of claim 1, further comprising a buffer layer disposed between the semiconductor substrate and the back gate insulating layer pattern.

11. A method of forming a semiconductor device, comprising:
forming a back gate trench in a predetermined region of a semiconductor substrate;
forming a back gate insulating layer pattern that covers at least a bottom surface of the back gate trench; and
forming a semiconductor layer that is disposed on the back gate insulating layer pattern and fills the back gate trench,
wherein the semiconductor layer has a same crystalline structure as the semiconductor substrate adjacent to the back gate insulating layer pattern.

12. The method of claim 11, wherein the forming of the back gate insulating layer pattern comprises:
forming a back gate insulating layer that conformally covers the back gate trench; and
forming the back gate insulating layer pattern that etches the back gate insulating layer to expose an upper surface of the semiconductor substrate adjacent to the back gate trench and covers at least a bottom surface of the back gate trench.

13. The method of claim 12, wherein the etching of the back gate insulating layer comprises:
forming a buffer layer filling the back gate trench on the back gate insulating layer; and
etching the buffer layer and the back gate insulating layer until an upper surface of the semiconductor substrate adjacent to the back gate trench is exposed.

14. The method of claim 13, wherein after the etching of the buffer layer and the back gate insulating layer, further comprising removing the buffer layer to expose an upper surface of the back gate insulating layer pattern.

15. The method of claim 13, wherein the semiconductor layer fills the back gate trench on which the buffer layer remains.

16. A method of claim 13, further comprising etching the back gate insulating layer to expose a sidewall of the back gate trench.

17. The method of claim 11, wherein the forming of the semiconductor layer comprises:
depositing a semiconductor material layer that is directly in contact with the semiconductor substrate on the back gate insulating layer pattern; and
annealing the semiconductor material layer so that the semiconductor material layer has a single crystalline structure transferred from the semiconductor substrate, and
wherein a crystalline structure of the semiconductor material layer is one of an amorphous structure or a polycrystalline structure.

18. The method of claim 17, wherein before or after the annealing of the semiconductor material layer, further comprising planarizing the semiconductor material layer down to an upper surface of the semiconductor substrate.

19. The method of claim 11, wherein the forming of the semiconductor layer comprises:
forming the semiconductor layer that fills the back gate trench using the semiconductor substrate adjacent to the back gate insulating layer pattern as a seed layer by a selective epitaxial growth technique; and
planarizing the semiconductor layer down to an upper surface of the semiconductor substrate.

20. The method of claim 11, wherein after the forming of the semiconductor layer, further comprising:
forming a gate insulating layer on the semiconductor layer;
forming at least one gate electrode on the gate insulating layer; and
forming impurity regions in the semiconductor substrate adjacent to the gate electrode or in the semiconductor layer, and
wherein the impurity regions have a conductivity type different from the semiconductor substrate.
